(19) United States
(12) Patent Application Publication
(10) Pub. No.: US 2004/0084606 A1
(43) Pub. Date: May 6, 2004

(54) Scanner

(76) Inventors: Ter-Ming Tang, Taipei (TW); Chia-Yang Chen, Taipei (TW)

Correspondence Address: BIRCH STEWART KOLASCH & BIRCH, PO BOX 747, FALLS CHURCH, VA, 22040-0747, US

(21) Appl. No.: 10/449,075

(22) Filed: Jun. 2, 2003

(30) Foreign Application Priority Data
Oct. 31, 2002 (TW) 091217468

(51) Int. Cl. H01L 27/00

(52) U.S. Cl. 250/208.1

(57) ABSTRACT

The present invention provides an image reading apparatus including a module, a base, a first guide rail, and a second guide rail. The module is provided to detect the images and has at least an image sensor. The base is provided to support the module. The first rail is used to guide the base to move along the first direction so as to provide the module detecting the first row of a document. The second rail is used to guide the base to move along the second direction so as to provide the module detecting the next row of the document. The image reading apparatus of the present invention is applied to a scanner or a fax machine.

### CROSS REFERENCE TO RELATED APPLICATIONS

This Application claims priority to Taiwan Patent Application No. 091217468 entitled “Scanner”, filed Oct. 31, 2002.

### FIELD OF THE INVENTION

The present invention relates to an image reading apparatus, and more particularly, to a low cost image reading apparatus.

### BACKGROUND OF THE INVENTION

As shown in FIG. 5 and FIG. 6, traditional scanners and fax machines have a plurality of linear image detecting modules 1, on which a plurality of image sensors 5 are disposed and configured to parallel each other. Generally, the length of linear image detecting module 1 is fixed for specific application, e.g. A4 size scanning. Therefore, the resolution of the application decides the required number of image sensors. Typical image sensors may be charge coupled devices (CCD) or contact image sensors (CIS).

Typical flatbed scanners use the linear image detecting module 1 moving along a vertical direction 3 to scan documents. Therefore, scanning of documents with size smaller than the length of module 1 may cause the waste of image sensors thereon.

In addition, typical scanner uses additive process to generate the image by reading signals of red, green, and blue colors. On the contrary, the print technology uses subtracting process to produce the image by reading signals of cyan (C), magenta (M), and yellow (Y) colors. A user has to transform the RGB signals obtained from the scanner into the CMY signals sending to the printer for printing process. The transform process may cause undesired image distortion. It is desirable to have a novel technique to resolve the problem.

### SUMMARY OF THE INVENTION

One aspect of the present invention provides a simple structure and low cost image reading apparatus for a scanner or a fax machine.

Another aspect of the present invention also provides a scanner reading cyan, magenta, yellow colors.

An image reading apparatus, including a module, a base, a first guide rail and a second guide rail is provided. The module detects images and is located on the base. The first guide rail guides the base to move along a first direction. The second guide rail guides the first guide to move along a second direction perpendicular to the first direction.

### BRIEF DESCRIPTION OF THE DRAWINGS

FIG. 1 shows how a module of the present invention applied to a scanner.

FIG. 2 shows a module and image sensors of the present invention.

FIG. 3 shows the moving directions of the module.

FIG. 4 shows how the module of the present invention applied to a fax machine.

FIG. 5 shows a scanner according to prior art.

FIG. 6 shows an module according to prior art.

### DETAILED DESCRIPTION OF THE INVENTION

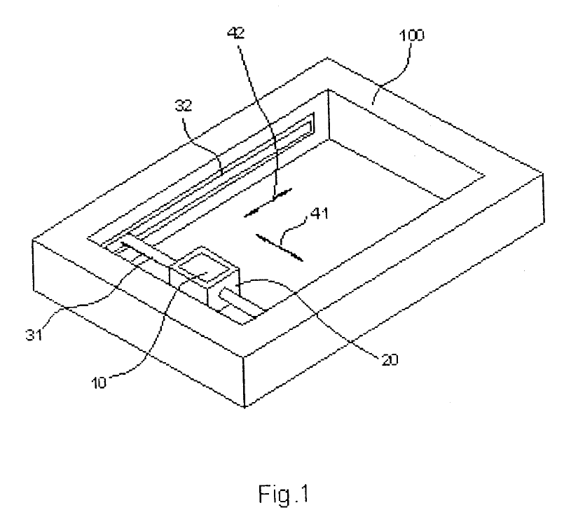

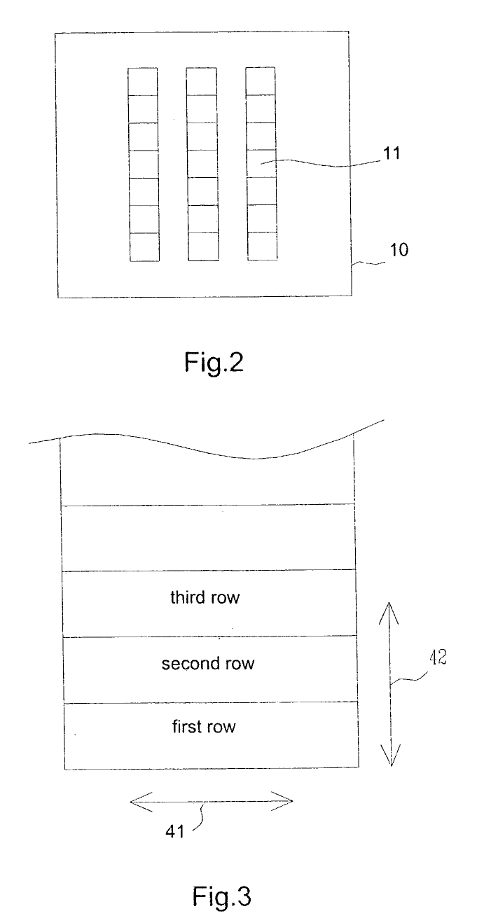

FIG. 1 shows a scanner 100 of the embodiment of present invention. The scanner 100 includes a module 10, a base 20, a first guide rail 31 and a second guide rail 32. The module 10 is used to detect images and is located within the base 20. As shown in FIG. 2, the module has a plurality of image sensors 11. The base 20 slidably assembles with the base 20 first guide rail 31 to move along a first direction 41. The first guide rail 31 slidably assembles with the second guide rail 32 to move along a second direction 42 which is perpendicular to the first direction 41.

The image sensors 11 may be charge coupled devices or contact image sensors. The module 10 may be a monochrome image detecting module or a color image detecting module.

FIG. 3 shows the directions along which the module 10 moves. During the scan process, the module 10 moves along the first direction 41 by moving along the first guide rail 31 and reads the first row data of the document 60. After reading the first row data, the first guide rail 31 moves a distance along the second direction 42 by moving along the second guide rail 32. Then, base 20 repeats the movement along the first direction 41 on the first guide rail 31, and reads the second row data of the document 60. Repeating the steps above until the contents of document is scanned.

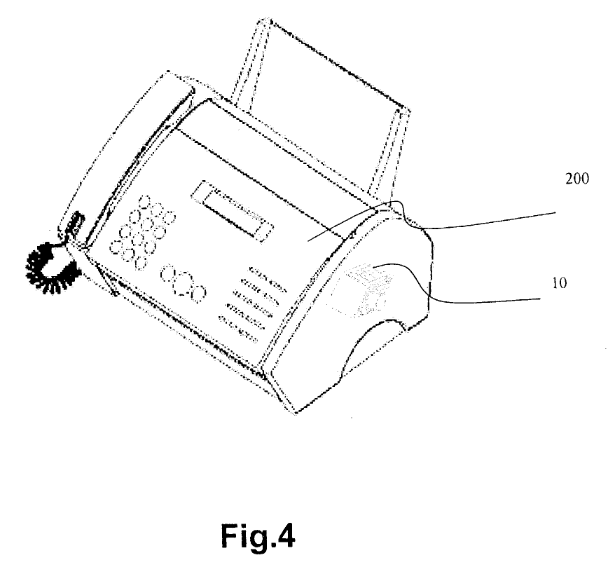

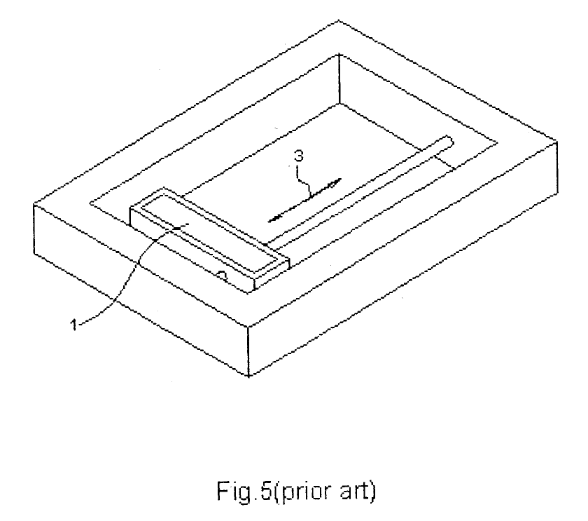

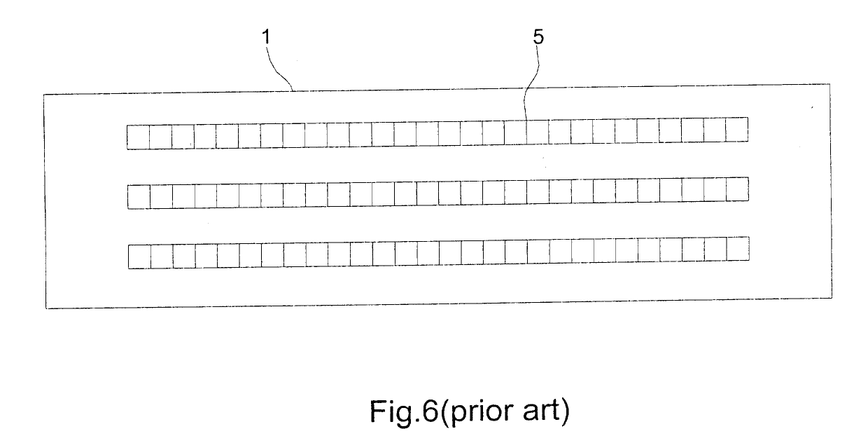

The module 10 of the embodiment may be applied to a fax machine 200 as shown in FIG. 4. The module 10 replaces the traditional linear image detecting module 1. However, the module 10 in this application has no need to move along the second direction 42 shown in FIG. 3.

Due to the capability of movement of module 10 along the direction 41, the present invention uses less image sensors 11 than the traditional image detecting module 1 uses for scanning same image area.

In addition, the present invention uses image sensors 11 capable of reading cyan, magenta, and yellow colors. The scanner 100 directly stores CMY values while the document 60 is a color image. A printer may directly print the image after the document 60 is scanned by the present invention.

While this invention has been described with reference to an illustrative embodiment, this embodiment should not be construed in a limiting sense. Various modifications of the illustrative embodiment, as well as other embodiments of the invention, will be apparent to persons skilled in the art upon reference to this description. It is therefore contemplated that the appended claims will cover any such modifications or embodiments as falling within the true scope of the invention.

1. An image reading apparatus for use in an image processing device, comprising:
a base;
a module for detecting an image, said module being supported by said base and comprising a plurality of image sensors; and
a first guide rail for slidingly assembling with said base to guide said base to move along a first direction.

2. The apparatus of claim 1, further comprising a second guide rail for slidingly assembling with said first guide rail to guide said first guide rail to move along a second direction, said first direction being perpendicular to said second direction.

3. The apparatus of claim 1, wherein said image processing device comprises a scanner.

4. The apparatus of claim 1, wherein said image processing device comprises a fax machine.

5. The apparatus of claim 1, wherein said plurality of image sensors comprise contact image sensors.

6. The apparatus of claim 1, wherein said plurality of image sensors comprise charge coupled devices (CCD).

7. The apparatus of claim 1, wherein said module comprises a monochrome image-detecting module.

8. The apparatus of claim 1, wherein said module comprises a color image-detecting module.

9. The apparatus of claim 1, wherein said plurality of image sensors comprise sensors reading cyan, magenta, yellow colors.
